(19) United States
(12) Patent Application Publication
(10) Pub. No.: US 2008/0130365 A1
(43) Pub. Date: Jun. 5, 2008

(54) BITLINE SELECTION CIRCUITRY FOR NONVOLATILE MEMORIES

(75) Inventor: Marylene Combe, Rousset (FR)

Correspondence Address: SCHNECK & SCHNECK, P.O. BOX 2-E, SAN JOSE, CA, 95109-0005, US

(73) Assignee: Atmel Corporation, San Jose, CA (US)

(21) Appl. No.: 12/017,297

(22) Filed: Jan. 21, 2008

Related U.S. Application Data
(63) Continuation of application No. 11/120,894, filed on May 3, 2005.

(30) Foreign Application Priority Data
Feb. 3, 2005 (FR) 05/01084

(51) Int. Cl. G11C 16/06

(52) U.S. Cl. 365/185.11; 365/185.25

(57) ABSTRACT

Bit lines of a memory device are arranged by an interleaving of even and odd bit lines and segregated into an even and odd bank. A discharge network discharges the banks alternately. A bit line selection network alternately connects the banks to a sense amplifier. The bank of odd bit lines is discharged just prior to a selection of the bank of even bit lines for reading and vice-versa.

Interleaving even and odd bit lines in combination with alternating selection and discharge of banks reduces a cross coupling voltage. A discharge delay ensures that a sense amplifier does not detect any signal during a discharge phase. The discharge delay is much shorter than the cross coupling delay required with no discharge scheme present. Discharging complementary banks of bit lines plus reduced discharge delay ensures that along with a short access time, correct data are detected by the sense amplifier.

### CROSS-REFERENCE TO RELATED APPLICATION

This application is a continuation of U.S. patent application Ser. No. 11/120,894 filed May 3, 2005.

### TECHNICAL FIELD

The invention relates to read operations in nonvolatile memories. More specifically, the invention reduces delay in nonvolatile memory read operations by minimizing cross coupling voltage effects between bit lines.

### BACKGROUND ART

Nonvolatile memories, known as flash memory devices, have become very popular in a variety of uses including mobile phones, digital answering machines, and personal digital voice recorders. Low pin count, low cost, and ease-of-use are key factors for the wide utilization of flash memory.

With respect to FIG. 1, a prior art flash memory device 100 is composed of a matrix of memory cells. An array of bit lines 110ₐ-110ₙ connect memory cells to a selection network 120. An array of word lines 115ₐ-115ₙ carry selection signals for parallel memory locations. The selection network 120 controls which bit lines 110ₐ-110ₙ are connected to a sense amplifier 130 for reading.

With respect to FIG. 2, the prior art selection network 120 (FIG. 1) of the flash memory device 100 is a first array of select transistors 210ₐ-210_{g} connecting bit lines 110ₐ-110_{g} to a first bank select transistor 215 and a second array of select transistors 210ₕ-210ₙ connecting bit lines 110ₕ-110ₙ to a second bank select transistor 225. Control signals applied to the first bit line select transistor 210ₐ and the first bank select transistor 215 allow the sense amplifier 130 to read a memory cell on the first bit line 110ₐ. Remaining memory cells are selected similarly with the use of an array of word lines (not shown).

With respect to FIG. 3, in a prior art bit line schematic diagram 300, an array of memory cells 305ₐ-305_{g} connects to the array of bit lines 110ₐ-110_{g}. Bit lines 110ₐ-110_{g} have an associated bit line loading capacitance 310ₐ-310_{g} to ground and a bit line coupling capacitance 320ₐ-320_{g} between adjacent lines. The bit line select transistors 210ₐ-210_{g} connect the bit lines 110ₐ-110_{g} to the first bank select transistor 215. A control signal applied to the gate of the first bank select transistor 215 connects a selected bit line to the sense amplifier 130.

A bit line selection waveform diagram 400 of FIG. 4 includes a first bit line select pulse 410 applied to a first bit line select transistor 210ₐ (FIG. 3) to begin a read operation. The first bit line 110ₐ is precharged to a high-voltage level prior to reading a first memory cell 305ₐ. A first bank select pulse 430 activates the first bank select transistor 215, connecting the sense amplifier 130 to the first bit line 110ₐ. If the first memory cell 305ₐ is on, the sense amplifier 130 senses the current being drawn through the cell.

A second bit line select pulse 420 applied to a second bit line select transistor 210_{b} begins a path to the second memory cell 305_{b}. The second memory cell 305_{b} is connected through the second bit line select transistor 210_{b} and the first bank select transistor 215 to the sense amplifier 130. Cross coupling between bit lines allows a cross coupling current 330 to flow through the first memory cell 305ₐ, the first bit line 110ₐ, the first bit line coupling capacitance 320ₐ, the second bit line select transistor 210_{b}, and the first bank select transistor 215 to the sense amplifier 130. If the second memory cell 305_{b} is off and a first memory cell 305ₐ is on, this cross coupling path causes a cell-read problem.

A precharged high-voltage level on the first bit line 110ₐ is a remnant from the first read operation. The high-voltage level is discharged through the first memory cell 305ₐ resulting in a first bit line voltage response 450. The first bit line coupling capacitance 320ₐ allows a second bit line current response 460 to be produced from the first bit line voltage response 450. During the cross coupling activity of the second bit line current response 460, the sense amplifier 130 detects the first memory cell 305ₐ being on but the control signals are selecting the second memory cell 305_{b} which is off. In this case, incorrect data are read.

The length of time that the second bit line current response 460 remains above a sense amplifier threshold 464 defines a cross coupling delay 465. The cross coupling delay 465 is that period of time necessary to delay a read operation for a second memory cell in order to avoid the sense amplifier 130 reading incorrect data. Therefore, reading of the prior art flash memory device 100 is significantly delayed due to a wait period inherent in the cross coupling delay 465 between each read operation. Waiting for the cross coupling delay 465 between each read operation slows down the overall reading of the flash memory device 100 significantly.

### DISCLOSURE OF INVENTION

Bit lines of a memory device are arranged by an interleaving of even and odd bit lines and segregated into an even and odd bank. A discharge network discharges the banks alternately. A bit line selection network alternately connects the banks to a sense amplifier. The bank of odd bit lines is discharged just prior to a selection of the bank of even bit lines for reading and vice-versa.

Interleaving of even and odd bit lines in combination with alternating selection and discharge of banks reduces a cross coupling voltage. A discharge delay ensures that a sense amplifier does not detect any signal during a discharge phase. The discharge delay is much shorter than the cross coupling delay required with no discharge scheme present. Discharging complementary banks of bit lines ensures that along with a short access time, correct data are detected by the sense amplifier.

### BRIEF DESCRIPTION OF DRAWINGS

FIG. 1 is a block diagram of a prior art flash memory device incorporating a selection network.

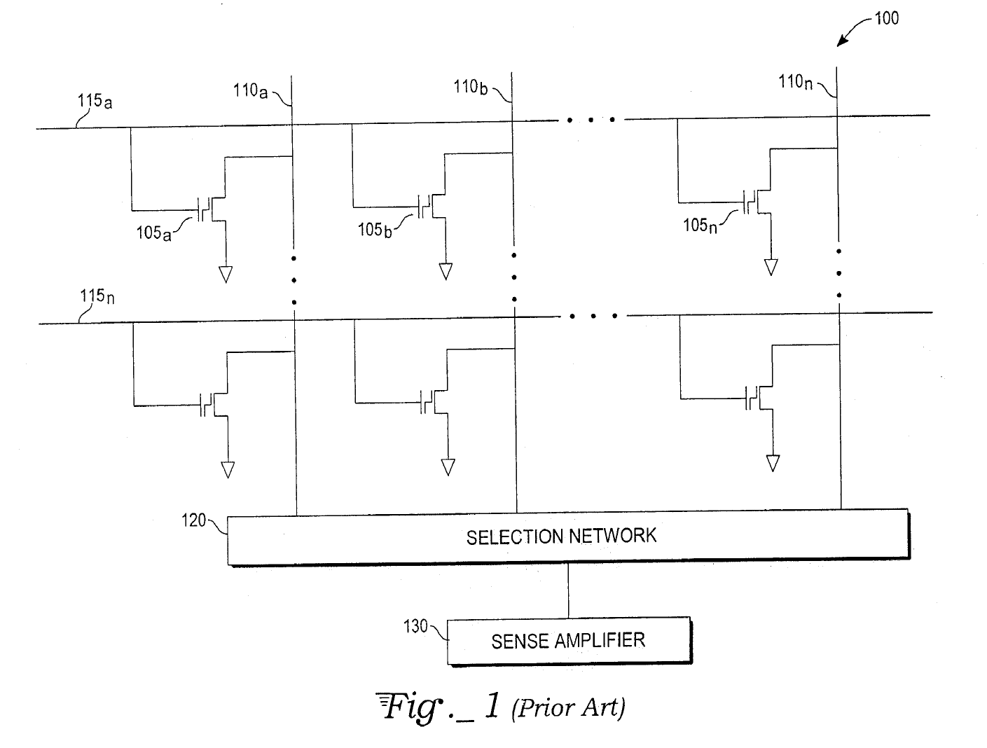

FIG. 2 is a block diagram of the prior art selection network of FIG. 1.

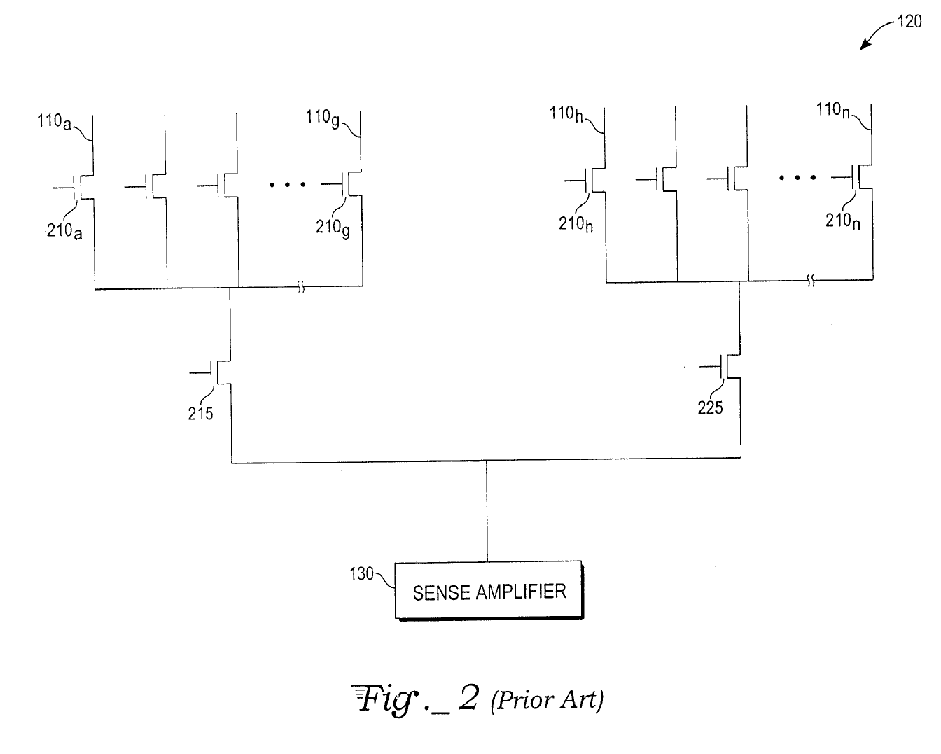

FIG. 3 is a block diagram of a single bank of the prior art selection network of FIG. 2 indicating coupling capacitance and cross coupling current.

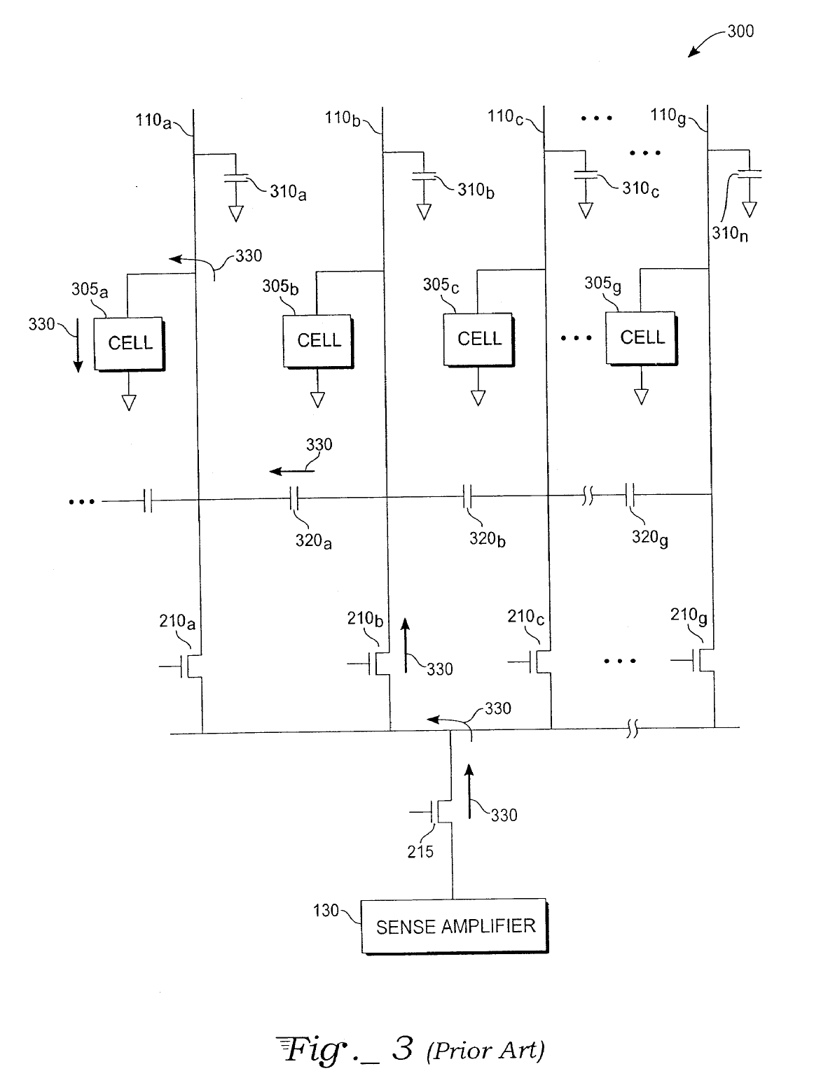

FIG. 4 is a waveform diagram of a prior art bit line and bank selection process of the block diagram of FIG. 3.

FIG. 5 is a block diagram of a selection network of the present invention.

FIG. 6 is a waveform diagram of the present invention with a bit line and bank selection process of the block diagram of FIG. 5.

FIG. 7 is an exemplary process flow diagram of the present invention in a sequential read operation incorporating an alternating discharge scheme.

FIG. 8 is an exemplary process flow diagram of the present invention in a sequential read operation incorporating a previous location discharge scheme.

FIG. 9 is an exemplary process flow diagram of the present invention in a sequential read operation incorporating an adjacent locations discharge scheme.

### MODES FOR CARRYING OUT THE INVENTION

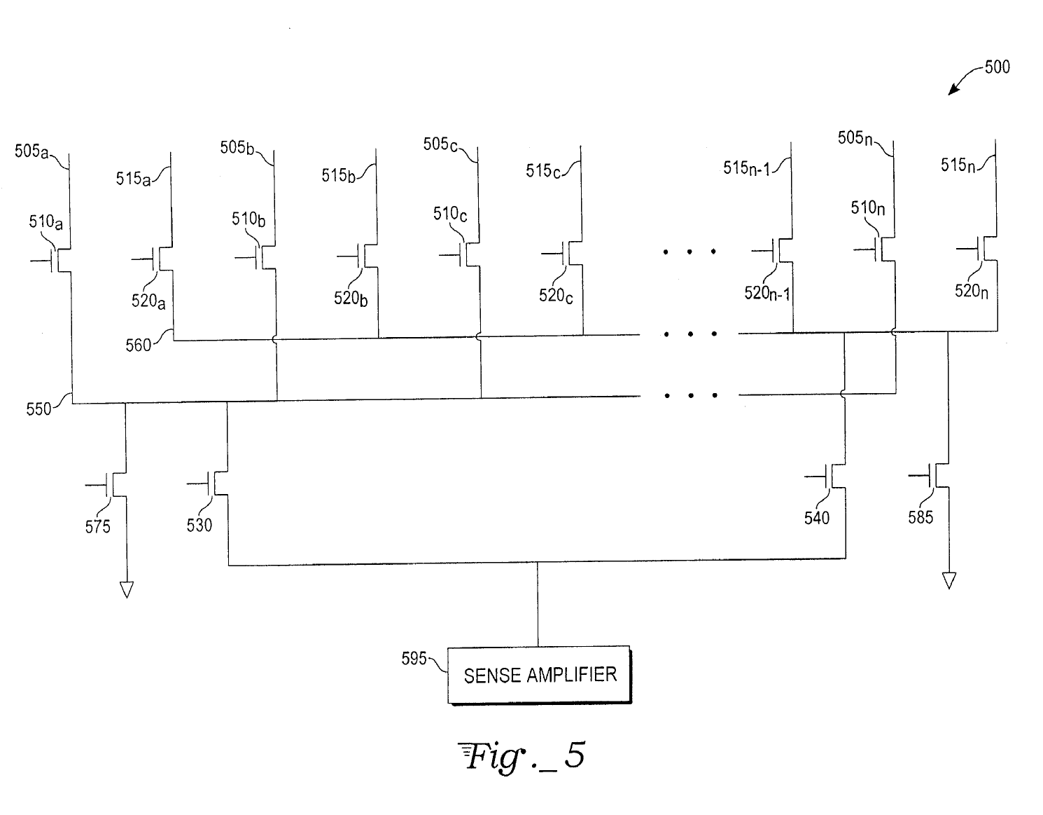

With reference to FIG. 5, a bank of odd bit lines 505ₐ-505ₙ and a bank of even bit lines 515ₐ-515ₙ feed into an exemplary bit line selection network 500 of the present invention. Even and odd bit lines from the two banks are interleaved. Odd selection transistors 510ₐ-510ₙ connect the bank of odd bit lines 505ₐ-505ₙ to an odd junction bus 550. Even select transistors 520ₐ-520ₙ connect the bank of even bit lines 515ₐ-515ₙ to an even junction bus 560. An even bank select transistor 540 connects the even junction bus 560 to a sense amplifier 595. An odd bank select transistor 530 connects the odd junction bus 550 to the sense amplifier 595. An odd bank discharge transistor 575 connects the odd junction bus 550 to ground. The even junction bus 560 is connected to ground by an even bank discharge transistor 585.

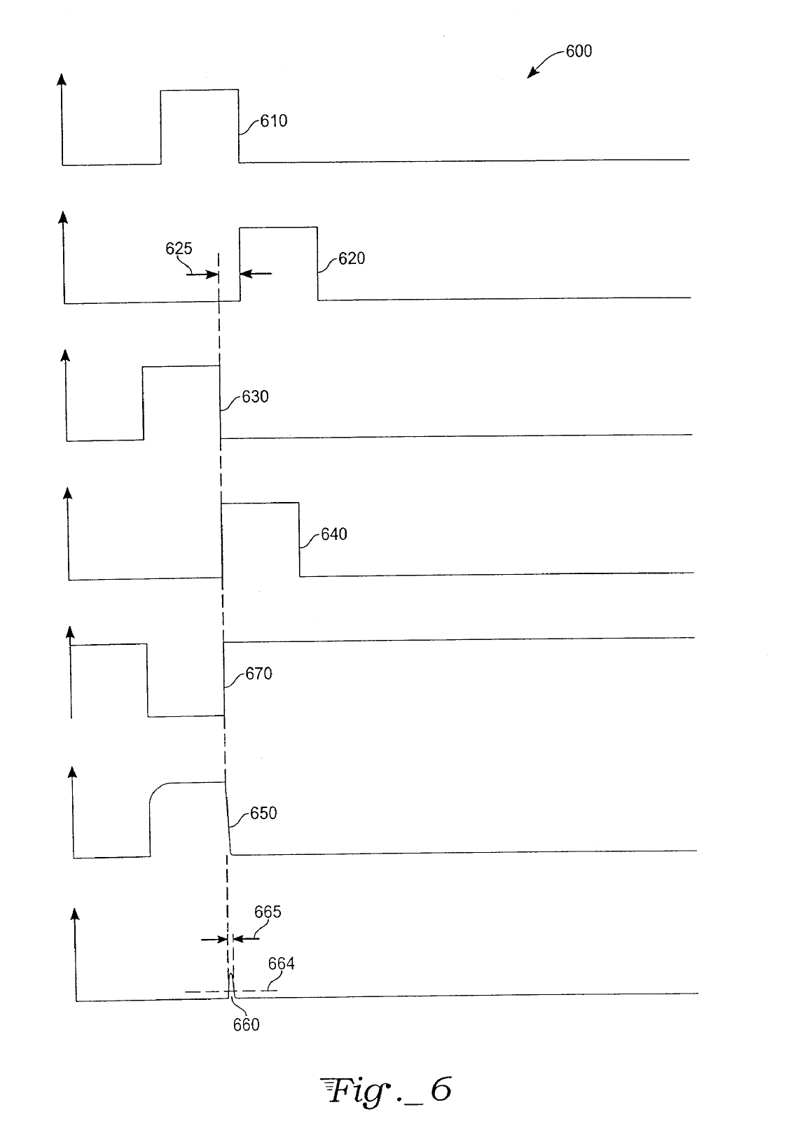

With reference to FIG. 6, an even bank select pulse 640, of an exemplary bit line selection waveform diagram 600, controls selection of the even junction bus 560 (FIG. 5). The bank of even bit lines 515ₐ-515ₙ is selectable when the even bank select pulse 640 is applied to the even bank select transistor 540. An odd bank select pulse 630 applied to an odd bank select transistor 530 selects the odd junction bus 550. A control signal (not shown) applied to the gates of the odd select transistors 510ₐ-510ₙ connects the bank of odd bit lines 505ₐ-505ₙ to the odd junction bus 550.

A control signal applied to the odd select transistors 510ₐ-510ₙ and an odd bank select-bar pulse 670 applied to the odd bank discharge transistor 575 discharges the bank of odd bit lines 505ₐ-505ₙ Alternatively, the adjacent two odd bit lines of an even bit line to be read may be selected for discharge. The odd bank select-bar pulse 670 is the complement of the odd bank select pulse 630. Therefore, the bank of odd bit lines 505ₐ-505ₙ discharges when the bank of odd bit lines 505ₐ-505ₙ is not selected. An even bank select-bar pulse (not shown) operates similarly in comparison with the even bank select pulse 640, the even select transistors 520ₐ-520ₙ, and the bank of even bit lines 515ₐ-515ₙ.

The sense amplifier 595 (FIG. 5) drives a first bit line voltage response 650 high during the time the bit line is selected for reading which is defined by a first bit line select pulse 610. The sense amplifier 595 performs a read operation by sensing the current in the first bit line 505ₐ while biased at a high voltage condition. At the end of the read operation, the odd bank select-bar pulse 670, driving the odd bank discharge transistor 575 and a control signal to the odd select transistors 510ₐ-510ₙ, connects the first bit line, along with the remainder of the bank of odd bit lines 505ₐ-505ₙ, to ground. The falling edge of the first bit line voltage response 650 depicts the discharge transition for the bank of odd bit lines 505ₐ-505ₙ.

During the discharge of the bank of odd bit lines 505ₐ-505ₙ, a second bit line current response 660 is detected if the sense amplifier 595 is enabled during this discharge period. The second bit line current response 660 may ascend through a sense amplifier threshold 664. Detection of this condition by the sense amplifier 595 indicates a conducting condition in the memory cell addressed on the second bit line. The width of this pulse in the second bit line current response 660 is a discharge delay 665 that defines an amount of time necessary to discharge any bit lines which may cause a cross coupling problem with the bit line about to be read. The discharge delay 665 is also a minimum of time required for delaying a second bit line select pulse 620 and for delaying activation of the sense amplifier 595 to read a succeeding location.

A bit line select delay 625 is defined to be greater than a worst-case value expected for the discharge delay 665. The bit line select delay 625 defines an amount of time the second bit line select pulse 620 (or any even bit line select pulse) is offset from application of the even bank select pulse 640. The bit line select delay 625 identically defines an amount of time the first bit line select pulse 610 (or any odd bit line select pulse) is offset from the odd bank select pulse 630. After the bit line select delay 625 has elapsed and the second bit line select pulse 620 is applied, the sense amplifier 595 is activated and reads the correct value within a memory cell on the second bit line 515ₐ.

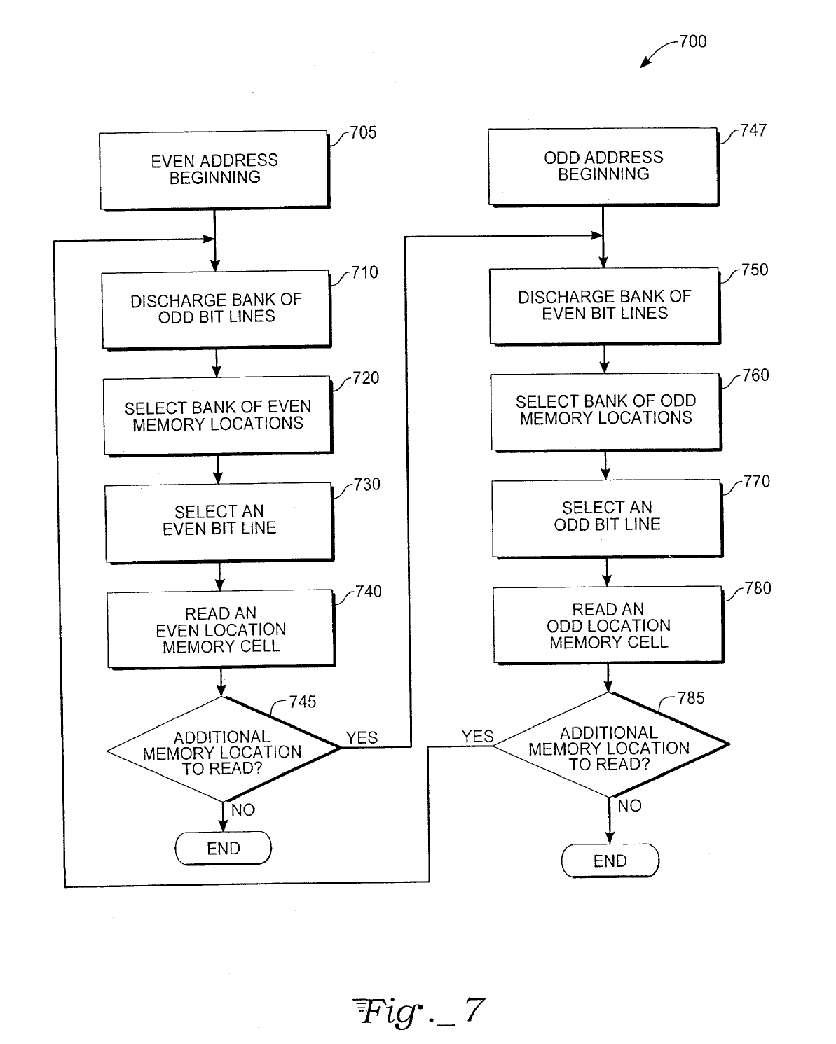

With reference to FIG. 7, an exemplary process flow diagram of an alternating bit line reading process 700 begins 705 a read operation at an even address with discharging 710 the bank of odd bit lines before selecting 720 the bank of even memory locations. The process 700 continues with selecting 730 an even bit line and reading 740 an even location memory cell. A determination 745 is made whether any additional memory location is to be read. If no additional memory location is to be read, the process 700 ends.

If a succeeding memory location is to be read the process continues with discharging 750 the bank of even bit lines and selecting 760 the bank of odd memory locations. The process continues with selecting 770 an odd bit line and reading 780 an odd location memory cell. A determination is made whether there is an additional memory location to read 785. If an additional memory location is to be read, the process iterates beginning with the discharging 710 of the bank of odd bit lines. Otherwise the process ends. For beginning 747 a read operation at an odd address the process commences with discharging 750 the bank of even bit lines and continues as discussed supra.

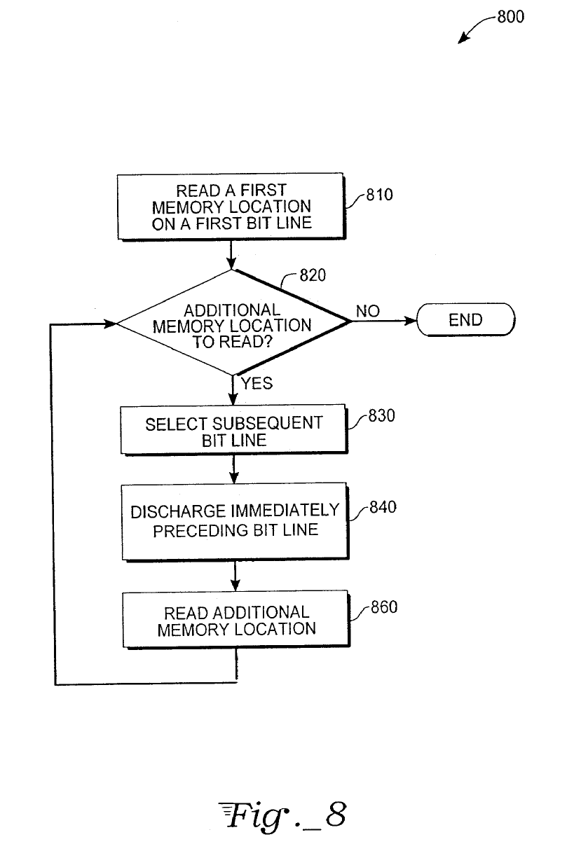

With reference to FIG. 8, an exemplary process flow diagram of a sequential read process 800 begins with reading 810 a first memory location on a first bit line and determining 820 whether an additional memory location is to be read. If there is no further memory location to be read the process ends. If there is a further memory location to be read, the process continues with selecting 830 a subsequent bit line and discharging 840 a bit line that immediately precedes the selection in time. The process proceeds with reading 860 the additional memory location. The process resumes with again making the determination 820 whether an additional memory location is to be read and proceeding accordingly.

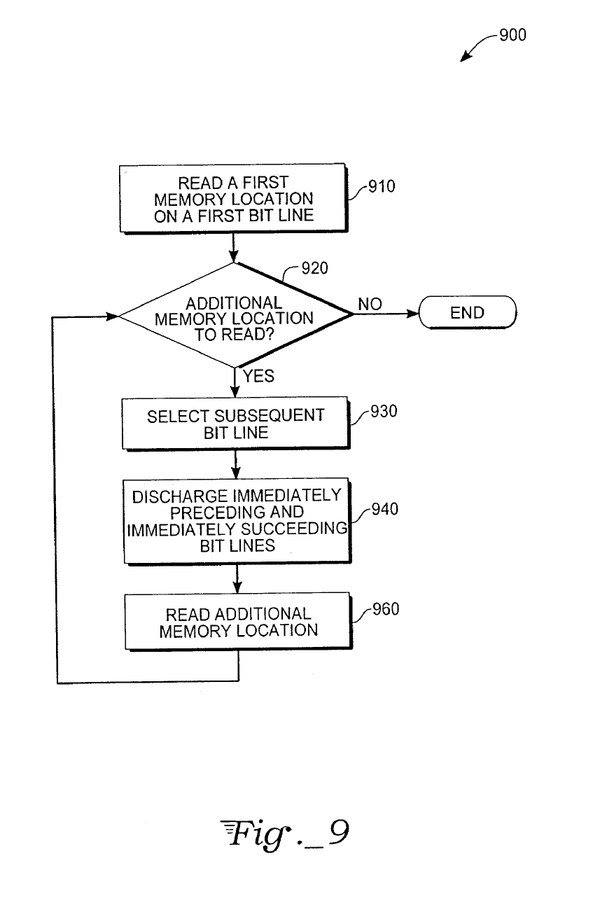

With reference to FIG. 9, an exemplary process flow diagram of a sequential read process 900 begins with reading 910 a first memory location on a first bit line and determining 920 whether an additional memory location is to be read. If there is no further memory location to be read the process ends. If there is a further memory location to be read, the process continues with selecting 930 a subsequent bit line and discharging 940 an immediately preceding bit line position and an immediately succeeding bit line position. The process proceeds with reading 960 the additional memory location. The process resumes with again making the determination 920 whether an additional memory location is to be read and proceeding accordingly.

In further regard to the exemplary process flow diagram of FIG. 9, a characterization is made by two even select transistors 520b, 520c (FIG. 5) being selected to discharge two even bit lines 515b, 515c adjacent to an odd bit line 505c before the odd bit line 505c is read. An analogous situation is true for reading an even bit line.

In an exemplary read process where two consecutive addresses to be read (not shown) are even (or odd), the first bit line read does not need discharging before reading the second bit line since the interleaved layout of even and odd bit lines prevents any coupling effects from causing a problem.

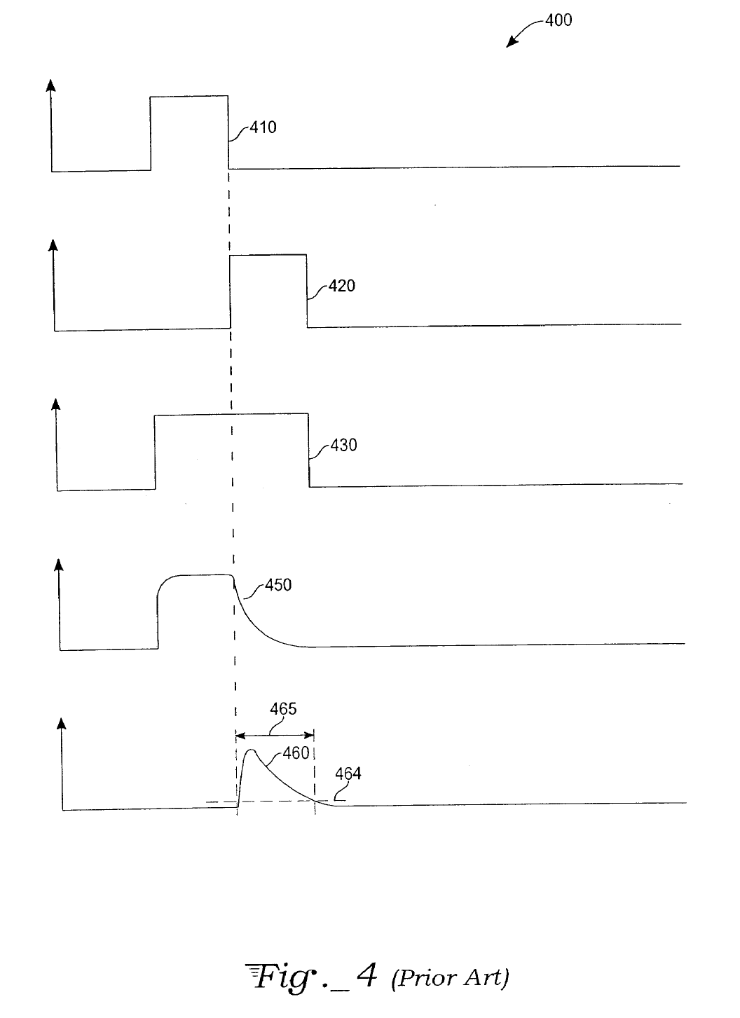

The use of segregation of bit lines into banks of even and odd bit lines and alternating the reading and discharging of the banks reduces the voltage potential for coupling on adjacent bit lines. This ensures that the magnitude of the bit line select delay 625 with the present invention is significantly reduced from the cross coupling delay 465 (FIG. 4) in the prior art bit line selection network where discharging is not incorporated. A similar reasoning holds for discharging the just prior memory location from the location to be read.

While the present invention has been described in terms of the use of a sensing means for reading operations, a skilled artisan in this field would readily identify the suitability of using a voltage comparator circuit, latch, sense amplifier, or cross coupled inverters to provide similar sensing capabilities. An apparatus for selection of bit lines has been described using single transistor devices in series between points to be coupled electrically. A person of skill in the art would also consider the use of a matrix of transmission gates, a crossbar switch, or a multiplexer for the same coupling purposes.

What is claimed is:

1. A bit line selection circuit comprising:
a plurality of bit lines arranged alternately into a first bank of even bit lines and a second bank of odd bit lines;
a sense amplifier coupled to the plurality of bit lines;
a discharge network coupled to the plurality of bit lines and configured to discharge the first and second banks in an alternating fashion thereby reducing a coupling capacitance between adjacent bit lines of the first bank of even bit lines and the second bank of odd bit lines; and
a bit line selection network configured to alternately couple the first bank and the second bank to the sense amplifier.

2. The bit line selection circuit of claim 1 wherein the discharge network is further configured to discharge the first bank of even bit lines while the second bank of odd bit lines is coupled to the sense amplifier and discharge the second bank while the first bank is coupled to the sense amplifier.

3. A memory circuit comprising:
a plurality of adjacent, interleaved, alternately odd and even bit lines segregated into two banks, a first bank of even bit lines and a second bank of odd bit lines;
a sensing means for separately reading one of the plurality of adjacent, interleaved, alternately odd and even bit lines; and
a discharge network configured to discharge the first bank and the second bank in an alternating fashion thereby reducing a coupling capacitance between proximate bit lines of the first bank of even bit lines and the second bank of odd bit lines.

4. The memory circuit of claim 3 further comprising a bit line selection means for coupling to a bit line and configured to alternately couple the sensing means separately to either the first bank or to the second bank.

5. The memory circuit of claim 3 wherein the first bank is configured to be discharged while the second bank is coupled to the sensing means and the second bank is configured to be discharged while the first bank is coupled to the sensing means.

6. A bit line selection circuit comprising:
a plurality of adjacent, alternately odd and even bit lines segregated into a first bank of even bit lines and a second bank of odd bit lines, the first and second banks being arranged such that the even bit lines and odd bit lines are alternately interleaved;
a sense amplifier coupled to the plurality of adjacent alternately odd and even bit lines;
a discharge network configured to alternately discharge the first bank and the second bank and reduce a coupling capacitance between adjacent bit lines of the first bank and the second bank; and
a pair of bit line selection apparatuses configured to separately couple the sense amplifier to the first bank and the second bank in an alternating fashion.

7. The bit line selection circuit of claim 6 wherein a first of the pair of bit line selection apparatuses is coupled to the first bank and a second of the pair of bit line selection apparatuses is coupled to the second bank.

8. The bit line selection circuit of claim 6 wherein the first bank is configured to be discharged while the second bank is coupled to the sense amplifier and the second bank is configured to be discharged while the first bank is coupled to the sense amplifier.

9. The bit line selection circuit of claim 6 further comprising a memory bank selection network coupled to an output of the pair of bit line selection apparatuses and to an input of the sense amplifier, the memory selection bank network configured to couple the sense amplifier to the pair of bit line selection apparatuses.

10. A method of selecting memory bit lines during reading, the method comprising:
arranging a plurality of adjacent alternately odd and even bit lines to be segregated into two memory banks, a first bank of even bit lines and even memory locations and a second bank of odd bit lines and odd memory locations;
electrically coupling the first and second banks and arranging the first and second banks with respect to each other by alternately interleaving even bit lines of the first bank with adjacent odd bit lines of the second bank; and
reducing a coupling capacitance between the first bank and the second bank by discharging the second bank of odd bit lines between the odd bit lines and respectively adjacent even bit lines.

11. The method of claim 10 further comprising:
selecting the first bank of even memory locations;
reading a memory cell associated with an even bit line in the first bank after the step of discharging the second bank of odd bit lines; and
reducing a coupling capacitance between the first bank and the second bank by discharging the first bank of even bit lines.

12. The method of claim 10 further comprising:
selecting the second bank of odd memory locations; and
reading a memory cell associated with an odd memory bit line in the second bank after the step of discharging the first bank of even bit lines.

13. A method of selecting memory bit lines during reading, the method comprising:
electrically coupling alternately, interleaving, adjacent bitlines of a first bank of even bit lines and a second bank of odd bit lines to a sense amplifier; and
reducing a coupling capacitance between bit lines in the first bank and adjacent bit lines in the second bank by discharging the second bank of odd bit lines separately from the even bit lines.

14. The method of claim 13 further comprising:
discharging the first bank while the second bank is coupled to a sensing means; and
discharging the second bank while the first bank is coupled to the sensing means.

15. The method of claim 13 further comprising:
selecting the first bank of even memory locations;
reading a memory cell associated with an even bit line in the first bank after the step of discharging the second bank of odd bit lines; and
reducing a coupling capacitance between the first bank and the second bank by discharging the first bank of even bit lines separately from the odd bit lines.

16. The method of claim 13 further comprising:
selecting the second bank of odd memory locations; and
reading a memory cell associated with an odd memory bit line in the second bank after the step of discharging the first bank of even bit lines.
